(19) United States
(12) Patent Application Publication
(10) Pub. No.: US 2003/0164784 A1
(43) Pub. Date: Sep. 4, 2003

(54) System and method for noise approximation

(76) Inventors: Amir Sagiv, Modi'in (IL); Avni Noam, Jerusalem (IL); Simcha Pearl, Kohav Hashahar (IL); Hagit Frankel, Jerusalem (IL)

Correspondence Address: Eitan, Pearl, Latzer & Cohen-Zedek, One Crystal Park, Suite 210, 2011 Crystal Drive, Arlington, VA, 22202-3709, US

(21) Appl. No.: 10/086,632

(22) Filed: Mar. 4, 2002

(51) Int. Cl. G06F 19/00; H03M 1/66

(52) U.S. Cl. 341/144; 700/109; 700/121

(57) ABSTRACT

A method and system for using a firmware solution to compensate for a hardware problem of a noise level with a high standard deviation.

### BACKGROUND OF THE INVENTION

There may be a certain amount of noise (including offset) in chips due to skew matter. This skew matter may be due to minor imperfections present during the production of chips. For example, a channel may be longer or shorter than the specification, which may cause an increase or decrease in the current flowing across a device.

When reading data received in a packet, it may be necessary to determine whether the energy pulses being read are noise or actual data. It may be possible to run tests on a chip set to determine the average noise level in a given production. It may then be possible to set a noise floor level to reflect this average noise. The dynamic range may be the value of the data peak minus the noise level. This dynamic range may lessen with an increase in noise level, and the data peaks may not remain sufficiently above the data level. The data level is defined herein as the data peak plus the noise level divided by two. Any given peak may be checked to see if it is above the preset noise level. If it is, then the pulse may be determined to be a data packet, and processing may commence. If not, the pulse may be considered to be noise and may not be processed. If the disc range is too small, pulses may be incorrectly identified either as data or as noise.

Furthermore, in the production process, one chip may differ slightly from another. If the standard deviation of the noise is large relative to the average noise level, mistakes in distinguishing noise from actual data may also occur. Thus, valid data packets may be dropped and noise may be read as data.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings, in which:

FIG. 1 is a block diagram illustration of a chip noise-determination system, in accordance with an embodiment of the present invention;

FIG. 2 is a block diagram illustration of a part of the chip noise-determination system of FIG. 1, in accordance with an embodiment of the present invention;

FIG. 3 is a block diagram illusion of a part of the chip noise-determination system of FIG. 1, in accordance with an embodiment of the present invention; and

FIGS. 4A and 4B are detailed flowchart illustrations of a method of chip noise-determination, according to an embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those of ordinary skill in the art that the present invention may be practiced without these specific details. In other instances, well-known methods, procedures, and components have not been described in detail so as not to obscure the present invention.

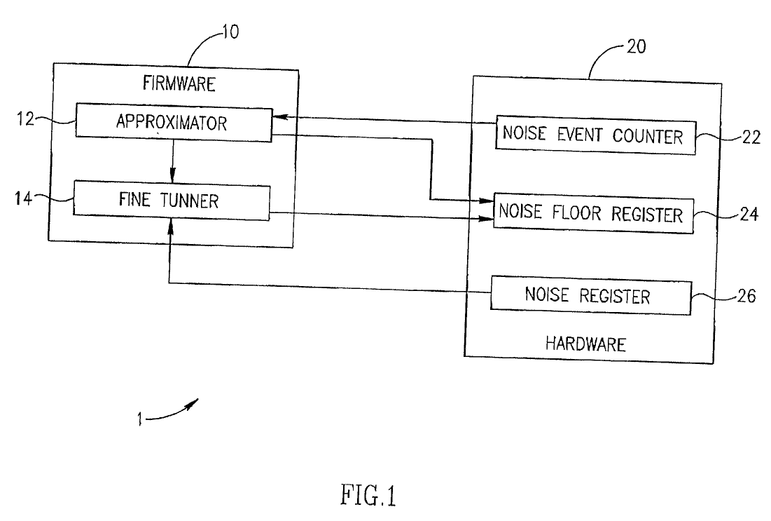

Reference is now made to FIG. 1, a block diagram illusion of a chip noise-determination system 1, which may comprise both a hardware component 20 and a firmware (or software) component 10, in accordance with an embodiment of the present invention. Firmware 10 may comprise an approximator 12 and a fine tuner 14. Hardware 20 may comprise, for example, three registers: a noise event counter 22, a noise floor register 24, and a noise register 26. It is noted that chip noise-determination system 1 may comprise other components and may contain different combinations of hardware and software components. Furthermore, hardware components may be implemented in software and software components may be implemented in hardware.

Approximator 12 may write to noise floor register 24 and may read from noise event counter 22. Fine tuner 14 may use the results produced by approximator 12. Fine tuner 14 may read from noise register 26 and may write to noise floor register 24.

Firmware 10 may embody, for example, a two-phase process in which approximator 12 may first provide a rough but rapid estimate of an appropriate noise floor level, and then fine tuner 14 may fine tune this estimate. This process may be rapid, since approximator 12 may read directly from noise event counter 22, and therefore it may not need to wait for feedback from the hardware. As fine tuner 14 may wait for feedback from noise register 26, this process may be slower.

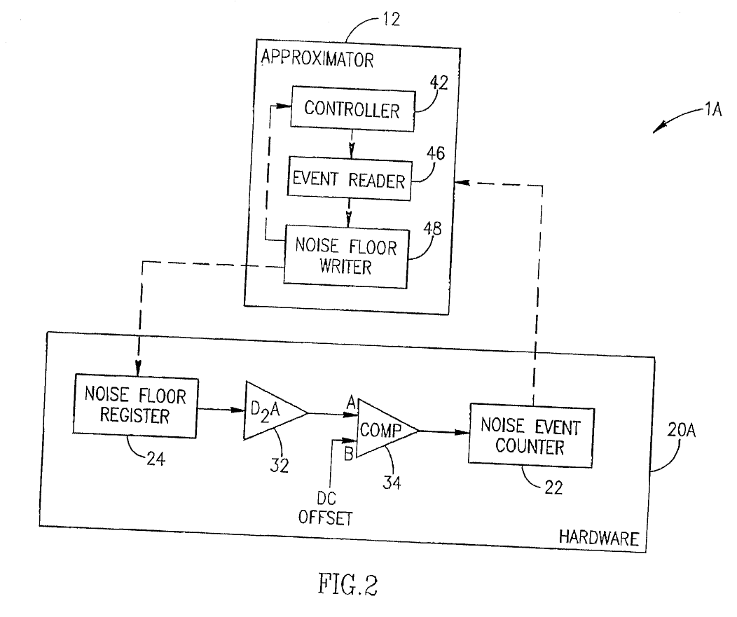

FIG. 2, to which reference is now made, is a detailed block diagram illustration of subsystem 1A, a part of chip noise-determination system 1, in accordance with an embodiment of the present invention. Subsystem 1A may comprise hardware 20A and approximator 12. Hardware 20A may comprise those parts of hardware 20 used by approximator 12. Hardware 20A may comprise noise floor register 24, a digital to analog converter (D/A) 32, a comparator 34, and noise event counter 22. Approximator 12 may comprise a controller 42, an event reader 46, and a noise floor writer 48. It is noted that subsystem 1A may comprise other components and may contain different combinations of components. Furthermore, hardware components may be implemented in software and software components may be implemented in hardware.

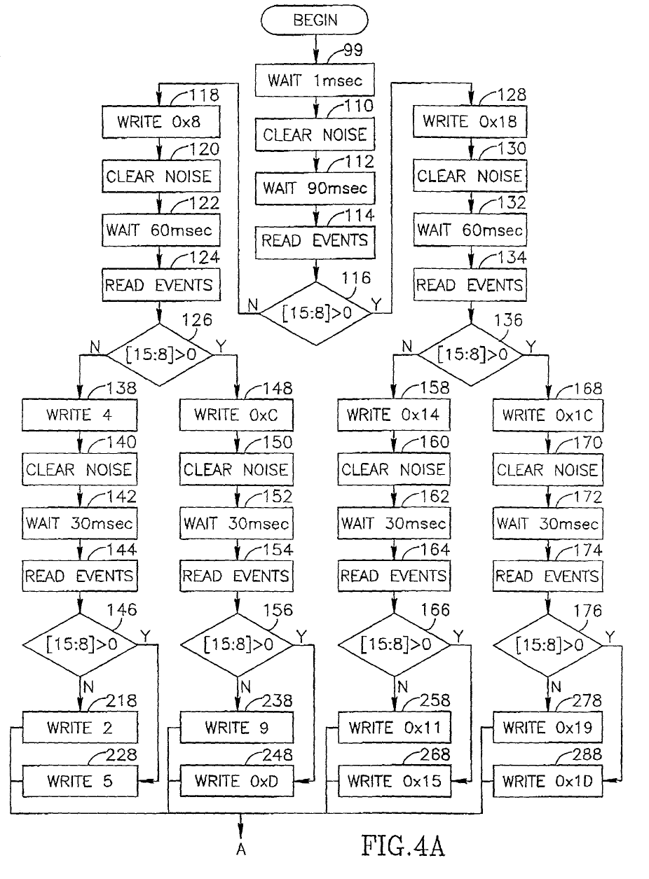

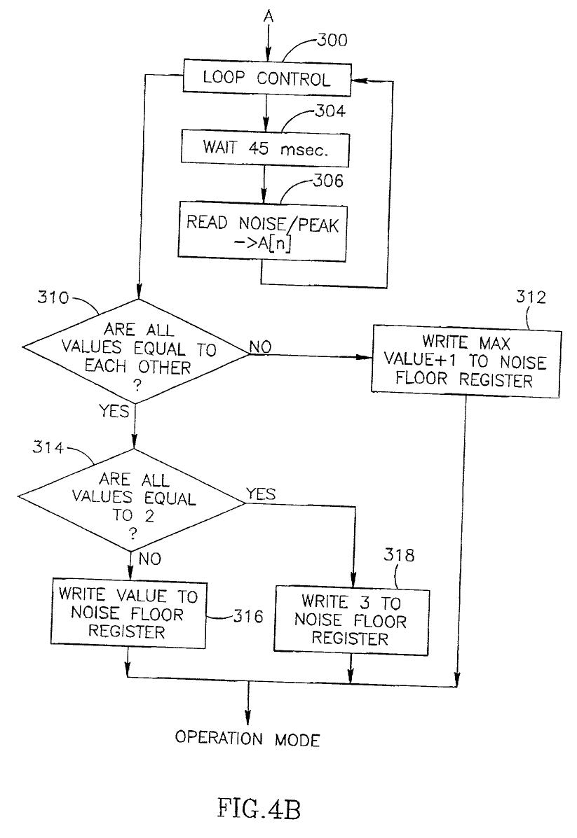

When a device comprising chip noise-determination system 1 is turned on, approximator 12 may be activated. Approximator 12 may have been preset to repeat its operation a given number of times. In the detailed example given hereinbelow with respect to FIG. 4A, the number of times is 3. At the beginning of each cycle, controller 42 may perform various initialization operations which may comprise initialization of hardware and firmware components. For example, a “wait time” may be set, and noise event counter 22 may be initialized to 0.

The “wait time” may be changed on each iteration run by approximator 12. For example, it may be decreased with each loop since, as the system equilibrates, the variation in noise may be less. Hereinbelow, exemplary wait times of 90, 60, and 30 milliseconds are used, however, other wait times are possible.

Tests may have been performed on the chips of a given production to determine the average chip noise floor value and its standard deviation. A value in the middle of the chip noise value range may have been selected, however, other values may be selected. The first time approximator 12 is run on startup of system 1A, noise floor register 24 may be initialized to the preselected initial noise floor value. Hereinbelow the exemplary value 0x10 will be used,

The value of noise floor register 24 may be sent to D/A 32. The resultant analog value may be input to comparator 34 as input A. The relevant direct current (DC) offset value, for example that of the chip receiver or transmitter, may be input as input B. Comparator 34 compares inputs A and B and may output an enable value, which may be true (when A is less the or equal to B) or false (when A is greater than B). If the enable value is true, noise event counter 22 may be enabled to count noise events. Alternatively, other enable values and tests may be used.

While approximator 12 is waiting, noise event counter 22 may be collecting noise events. After “wait time” has elapsed, event reader 46 may read the value in noise event counter 22. A portion of noise event counter 22 may be predesignated to contain the appropriate value. If this value is equal to “0”, for example, then no noise events may have been counted and the value “I” may be written to noise floor register 24; otherwise the value “J” may be written to noise floor register 24. Other values and counters may be used.

As will be explained in ether detail hereinbelow with respect to FIG. 4A, in an exemplary embodiment, the values I and J may be changed each time approximator 12 is run. This may be done so that the range of noise values within the standard deviation may be covered. Each time, the range to cover may be halved until a first approximation for the noise floor is reached. Other methods may be used to cover parts of the range of noise values differently.

Different chip sets may have different noise floor values and standard deviations. Thus, different values for I and J may be used depending on the production characteristics of a given chip set. Wait times may also be modified as appropriate for different productions.

Subsystem 1A may run only on chip start-up. In an exemplary embodiment of the present invention, subsystem 1A may be turned off, for example, after the initial noise floor approximation may have been written to noise floor register 24. This may result in less heat being produced and may require less energy consumption during the operation of the chip. Furthermore, it is noted that subsystem 1A may be used in place of those components in the analog portion of the chip that mimic the offset. It may then be possible to omit those components from the chip, which may result in significant space savings.

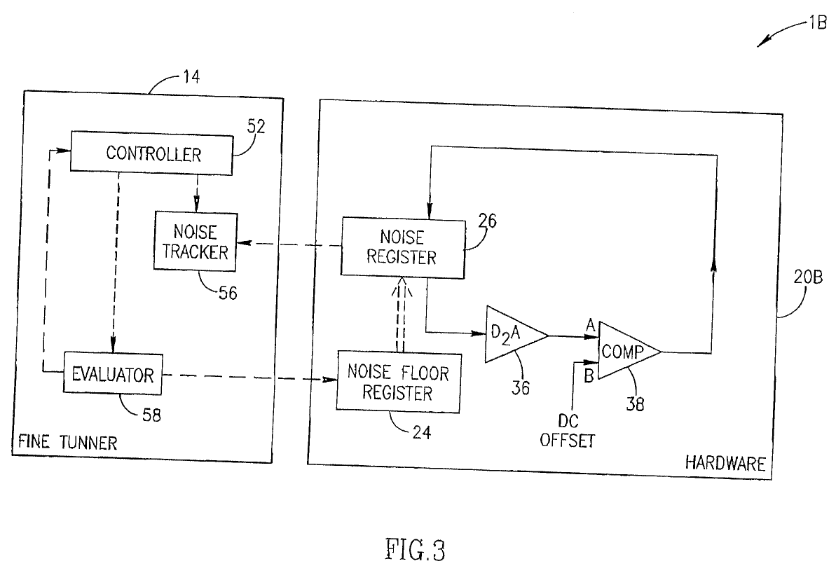

Reference is now made to FIG. 3, which is a detailed block diagram illustration of subsystem 1B, a part of chip noise-determination system 1, in accordance with an embodiment of the present invention. Subsystem 1B may comprise hardware 20B and fine tuner 14 in which hardware 20B may be working independently of fine tuner 14. Hardware 20B may comprise noise floor register 24, noise register 26, a D/A 36, and a comparator 38. Fine tuner 14 may comprise a controller 52, a noise tracker 56, and an evaluator 58. It is noted that noise floor register 24 may be the only hardware used in common by approximator 12 and fine tuner 14. It is noted that subsystem 1B may comprise other components and may contain different combinations of components. Furthermore, hardware components may be implemented in software and software components may be implemented in hardware.

Hardware 20B may be activated at given predetermined time intervals. This process may nm without any command being received from fine tuner 14. Noise floor register 24 may contain the value that was written by approximator 12. The value contained in noise floor register 24 may be written to noise register 26 by a control channel (double dashed lines).

The value contained in noise register 26 may be input to D/A 36. The analog output may be input to comparator 38 as input A. The current applicable DC offset value may be input to comparator 38 as input B. If input A is less than or equal to input B, the value in noise register 26 may be too low, and therefore it may be incremented for example, by 1. If input A is greater than input B, the value in noise register 26 may be too high and may be decreased, for example, by 1. However, the value in noise floor register 24 may serve as a lower bound for noise register 26 and, therefore, there may be cases in which noise register 26 may not be decremented in any case. Different tests may be used to determine if the value in noise register 26 should be incremented/decremented and by how much,

Thus, the value in noise register 26 may be increased/decreased each time hardware 20B is run. After a period of time, it may reach a state in which the value in noise register 26 alternates by changes of, for example, ±1 each cycle, in which case its value may be equal to the DC offset value. Alternatively, it may reach a state in which it has a value equal to that in noise floor register 24 but greater than the DC offset value.

Fine tuner 14 may use the components of hardware 20B. Controller 52 may perform various initialization and control operations. For example, the number of times noise register 26 will be read and the amount of time to wait between readings may be set. The amount of time to wait may be the same for each iteration of fine tuner 14. Different initializations are possible and different wait times may be used for different iterations.

Noise tracker 56 may read the value of noise register 26 and store its value a preset number of times. After the preset number of read and store operations have been performed, evaluator 58 may run. Evaluator 58 may compare the stored values from noise register 26 and may write a value to noise floor register 24. This will be explained in more detail hereinbelow with reference to FIG. 4B.

It may not be necessary for fine tuner 14 to be run except at predetermined times, for example, at system 1 startup.

Hardware 20B may run throughout operation of system 1, and, thus, changes in the noise levels in the environment in which the device is ruing may be detected. For example, the chip may be affected by electric current influences in a telephone wire. If, for example, a call is made on the telephone line, there may be increased noise in the chip due to the resultant electric/magnetic fields. The DC offset value may increase, which may cause the value in noise register 26 to be increased. When the interference ends, when, for example, the telephone call is terminated, the value of DC offset may decrease. The value in noise register 26 may be lowered as explained hereinabove.

FIGS. 4A and 4B, to which reference is now made, are detailed flowchart illustrations of an exemplary embodiment of the methods performed by approximator 12 and fine tuner 14 respectively, in accordance with an embodiment of the present invention. It is noted that other steps or series of steps may be used. A given chip production had an average noise level of 120 millivolts (mV) and a standard deviation of ±120. Most chips had noise levels that fell within an offset of ±160. Thus, to meet one industry standard it may be necessary to cover a range of 160 mV above and below the average noise level. Furthermore, a decimal value of 1 in noise floor register 24 may be converted to an analog value of 10 mV by D/A 32. Thus, in this exemplary production, 8 bits of a register may be used to represent a range of values from 0 to 0x20, which may be likely settings for a noise floor level for an individual chip.

FIG. 4A may be seen as three iterations of a loop, other numbers of iterations may be used. During processing, parameters may change for the wait time and for the values of I and J which may be written to noise floor register 24. Each loop may comprise, for example, 5 steps (corresponding steps are numbered with the same last digit). The steps of each loop may comprise,:

clearing noise event counter 22 (steps XX0, e.g. 110, 120, 130),

waiting a given amount of time (steps XX2, e.g. 112, 122, 132),

reading noise event counter 22 (steps XX4, e.g. 114, 124, 134),

checking if the value contained in the eight high order bits of noise event counter 22 is greater than 0, (steps XX6, e.g. 116, 126, 136), and

writing a value I or J to noise floor register 24 depending of result of check (steps XX8, e.g. 118, 128, 138).

It is noted that other steps or series of steps may be used. In this exemplary method, clearing noise and waiting may be performed by controller 42, reading and checking the value in noise event counter 22 may be performed by event reader 46, and writing to noise floor register 24 may be performed by noise floor writer 48 (of FIG. 2). Other combinations of steps and components are possible.

When the method is begun at system 1 startup, initialization may be performed. For example, the system may wait, for example, 1 msec and a value, for example, 0x10 may be written to noise floor register 24 (99).

Iteration 1: Noise event counter 22 may be cleared (110). Hardware 20A (FIG. 2) may convert the value written to noise floor register 24 into an analog signal using D/A 32. Comparator 34 may compare the analog signal to the DC offset and may enable or not enable noise event counter 22. The setting of noise event counter 22 may be done each time noise floor register 24 is modified or at predetermined intervals.

The firmware may wait, for example 90 msec (112). Noise event counter 22 may be read (114). In this embodiment, the eight high order bits 8 to 15 may be tested (116), as this may the part of the register in which the occurrence of noise events may be recorded. If the value is 0, no noise events were recorded and the value I=0x8 may be written to noise floor register 24 (118). If the value is greater than 0 then the value J=0x18 may be written to noise floor register 24 (128). Other embodiments wherein different bits, data formats, tests, and values may be used are possible.

By setting a new value, for example, halfway between 0 and 0x10 or halfway between 0x11 and 0x20, the range of possible values may be halved. If no events were interpreted as noise, the noise floor level may be too high and may, therefore, need to be lowered. If, however, there were events interpreted as noise, the noise floor level may be too low and may, therefore, need to be raised. This same logic may be used in each iteration, each time halving the range and thus possibly quickly arriving at a first escape for a noise floor level value. Other methods of dividing the range of possible values are possible.

Iteration 2: Noise event counter 22 may be cleared (120/130). The firmware may wait, for example, 60 msec (122/132). Noise event counter 22 may be read (124/134). The eight high order bits may be compared (126/136). The new values written to noise floor register 24 may vary depending on the value that was set in the previous iteration. If the previous value was, for example, 0x8, either the value I=4 (138) or J=0xC (148) may be written to noise floor register 24. If the previous value was, for example, 0x18, either the value I=0x14 (158) or J=0x1C (168) may be written to noise floor register 24. Other values, bits, and types of comparisons and comparison values are possible.

Iteration 3: There may now be, for example, four parallel paths. Noise event counter 22 may be cleared (140/150/160/170). The firmware may wait, for example, 30 msec (142/152/162/172). Noise event counter 22 may be read (144/154/164/174). The eight high order bits, for example, may be compared (146/156/166/176). The new values written to noise floor register 24 may again vary depending on the value that was set in the previous iteration. If the previous value was, for example, 4, either the value I=2 (218) or J=5 (228) may be written to noise floor register 24. If the previous value was, for example, 0xC, either the value I=9 (238) or J=0xD (248) may be written to noise floor register 24. If the previous value was, for example, 0x14, either the value I=0x11 (258) or J=0x15 (268) may be written to noise floor register 24. If the previous value was, for example, 0x1C, either the value I=0x19 (278) or J=0x1D (288) may be written to noise floor register 24. Other values, bits, and types of comparisons and comparison values are possible.

FIG. 4B is an exemplary embodiment of a method to fine tune the noise floor value which may have been written to noise floor register 24 by the method of FIG. 4A. Loop control may be implemented (300) and may comprise setting, incrementing, and checking a control variable for a given number of loop iterations; in the exemplary embodiment there are eight loop iterations. The firmware may wait, for example, 45 msec (304). Noise register 26 (FIG. 3) may be read and its value saved (306).

When the loop has finished execution, the saved values may be compared to each other (310). If all the values are not equal, the maximum value+1 may, for example, be written to noise floor register 24 (312). If all values are equal, whether they are equal to a given number, for example, 2 may be checked (314). If not, the value may be written to noise floor register 24 (316). If they are a equal to 2, then, for example, the value 3 may be written to noise floor remoter 24 (318). Different values may be written and different test values used.

An exemplary use, among others, for a chip comprising an embodiment of the present invention is to allow networking using telephony wires. The chip may be housed in a card or on a motherboard installed in a computer or other device. In the specification and the claims, the term “card” may be used to mean a board able to be installed in a computer or other device in order to provide the computer or other device with additional capabilities. A standard, which may be followed in implementing such an arrangement, is the HomePNA 1M8 protocol. Systems including such a card or motherboard may allow access to programs or devices from one element on the network to another. For example, there may be a home network system comprising two personal computers and one printer, in which the printer may be connected to only one of the personal computers. Use of the present invention may allow access from the personal computer not connected to the printer via the personal computer which is connected.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A system comprising:
a hardware component; and
a firmware component coupled to said hardware component and able to establish a noise level in a chip.

2. A system according to claim 1, wherein said noise level is a noise level of a receiver of said chip.

3. A system according to claim 1, wherein said noise level is a noise level of a transmitter of said chip.

4. A system according to claim 1, wherein said hardware comprises:
at least one digital to analog converter;
at least one comparator able to receive output of said converter;
at least one register able to be read by said firmware; and
at least one register able to be written to by said firmware.

5. A system according to claim 1, wherein said firmware comprises:
an approximator; end
a fine tuner able to fine tune the approximation of said approximator.

6. A method comprising
approximating a first noise level in an individual chip; and
fine tang said first noise level to produce a second noise level.

7. A method according to claim 6, wherein said approximating comprises:
determining said first noise level according to a hardware result.

8. A method according to claim 6, wherein said fine tuning comprises:
determining said second noise level according to a hardware result.

9. A method according to claim 6, wherein said approximating comprises:
reading from a noise event counter register; and
writing to a noise floor register.

10. A method according to claim 6, wherein said fine tuning comprises:
reading from a noise register; and
writing to a noise floor register.

11. A method comprising:
using a firmware solution to compensate for a hardware problem in a chip of a noise level with a high standard deviation.

12. A method according to claim 11, wherein said firmware solution is able to reduce energy consumption of a chip.

13. A method according to claim 11, wherein said firmware solution is able to reduce a space requirement of a hardware solution.

14. A system comprising:
a card; and
a chip attached to said card, said chip comprising:
a hardware component; and
a firmware component coupled to said hardware component and able to establish a noise level in said chip.

15. A system according to claim 14, wherein said noise level is a noise level of a receiver of said chip.

16. A system according to claim 14, wherein said noise level is a noise level of a transmitter of said chip.

17. A home phone networking system comprising:
two or more computers each having a chip comprising:
a hardware component; and
a firmware component coupled to said hardware component and able to establish a noise level in said chip.

18. A system according to claim 17, further comprising:
one or more peripheral devices coupled to at least one of said computers.
